(19) United States
(12) Patent Application Publication
(10) Pub. No.: US 2007/0178409 A1
(43) Pub. Date: Aug. 2, 2007

(54) Exposure method of forming three-dimensional lithographic pattern

(75) Inventor: Shih Chiang-Lin, Taipei (TW)

Correspondence Address: INGRASSIA FISHER & LORENZ, P.C., 7150 E. CAMELBACK, STE. 325, SCOTTSDALE, AZ, 85251, US

(73) Assignee: NANYA TECHNOLOGY CORP.

(21) Appl. No.: 11/453,481

(22) Filed: Jun. 14, 2006

(30) Foreign Application Priority Data
Jan. 27, 2006 (TW) 95103663

(51) Int. Cl. G03F 7/20

(52) U.S. Cl. 430/311; 430/394

(57) ABSTRACT

An exposure method of forming a three-dimensional lithographic pattern is provided. The method includes providing a substrate. A first photoresist layer is formed on the substrate. The first photoresist layer corresponds to a first exposure removal dose. A second photoresist layer is formed on the first photoresist layer. The second photoresist layer corresponds to a second exposure removal dose different from the first exposure removal dose. Through a first reticle, the first and second photoresist layers are exposed with a first exposure energy, which is in a range between the first exposure removal dose and the second exposure removal dose, so as to form a first removable region. Through a second reticle, the first and second photoresist layers are exposed with a second exposure energy, which is substantially equal to or higher than the higher one of the first exposure removal dose and the second exposure removal does, so as to form a second removable region different from the first removable region.

### FIELD OF INVENTION

The present invention generally relates to a method of forming a semiconductor device, and more particularly, to an exposure method of forming a three-dimensional lithographic pattern.

### BACKGROUND OF THE INVENTION

The fabrication of semiconductor devices generally repeatedly performs a series of processes including lithography, etch, deposition, doping, etc on a semiconductor wafer to form layer-stacked integrated circuits. Therefore, the formation of electrical contacts or connections between every layer is one of important processes during the fabrication of integrated circuit devices. As the device size shrinks and the integration density increases, however, the process window and the test limit become more and more rigorous, which particularly seriously influence the formation of the integrated circuit.

A three-dimensional structure, such as a dual damascene, a bottle-like capacitor, or any other three-dimensional device structure as appropriate, is generally required for the manufacture of a semiconductor device. A conventional method of forming a three-dimensional structure generally repeats steps of depositing, coating, exposing, developing, etc. so as to form a desired pattern in each layer respectively. For example, a dual damascene process is typically classified as a via first process flow and a trench first process flow. However, no matter the via first process flow or the trench first process flow is adpoted, the etch process and the lithography process are repeatedly performed on each layer so as to define a via and a trench, respectively. For example, in the via first process flow, the conventional method includes steps of coating a photoresist layer on a dielectric layer, patterning the photoresist layer with a via pattern in a first lithography process, and then etching the dielectric layer by using the patterned photoresist layer as a mask so as to form the via pattern in the dielectric layer. Then, another photoresist layer is coated on the dielectric layer with the via pattern. The photoresist layer is patterned to form a trench pattern in a second lithography process. Using the photoresist layer with the trench pattern as a mask, the dielectric layer is etched to form a trench so that a dual damascene pattern is created. However, the conventional method typically creates a single layer pattern in one lithography process, such as the via pattern or the trench pattern, resulting in the complication of the manufacture process flow of the integrated circuit. Consequently, the loading on the process equipment is heavily escalated, the production cost is increased, and the throughput is reduced.

Therefore, there is a need to provide an exposure method of forming a three-dimensional lithographic pattern, which can simplify the process flow, reduce the production cost, and increase the throughput.

### SUMMARY OF THE INVENTION

One aspect of the present invention is to provide an exposure method of forming a three-dimensional lithographic pattern, which implements multiple layers of photoresist and multiple reticles with multiple exposure steps in one lithographic process to form a three-dimensional pattern resulting in the simplification of process steps, the cost reduction, and the increase in throughput.

In one embodiment of the present invention, an exposure method of forming a three-dimensional lithographic pattern, such as a dual damascene pattern or a bottle-like pattern, is provided. The method includes a step of providing a substrate. Then, a first photoresist layer is formed on the substrate. The first photoresist layer corresponds to a first exposure removal dose. A second photoresist layer is formed on the first photoresist layer. The second photoresist layer corresponds to a second exposure removal dose, which is different from the first exposure removal dose. Through a first reticle, the first and the second photoresist layers are exposed with a first exposure energy so as to form a first removable region. The first exposure energy is in a range between the first exposure removal dose and the second exposure removal dose. Through a second reticle, the first and the second photoresist layers are then exposed with a second exposure energy so as to form a second removable region different from the first removable region. The second exposure energy is higher than the higher one of the first exposure removal dose and the second exposure removal dose.

In an exemplary embodiment, the first exposure removal dose is higher than the second exposure removal dose. The step of exposing with the first exposure energy forms the first removable region substantially only in the second photoresist layer. The step of exposing with the second exposure energy forms the second removable region substantially partially overlapping the first removable region. The method further includes a step of developing the first and the second photoresist layers so as to remove the first and the second removable regions.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of a substrate with two photoresist layers in accordance with one embodiment of the present invention;

FIG. 2A illustrates a cross-sectional view of exposing the substrate of FIG. 1 through a first reticle;

FIG. 2B illustrates a cross-sectional view of exposing the substrate of FIG. 2A through a second reticle;

FIG. 2C illustrates a cross-sectional view of removing removable regions of FIG. 2B;

FIG. 3A illustrates a cross-sectional view of exposing the substrate of FIG. 1 through a first reticle;

FIG. 3B illustrates a cross-sectional view of exposing the substrate of FIG. 3A through a second reticle; and

FIG. 3C illustrates a cross-sectional view of removing removable regions of FIG. 3B.

### DETAILED DESCRIPTION OF THE INVENTION

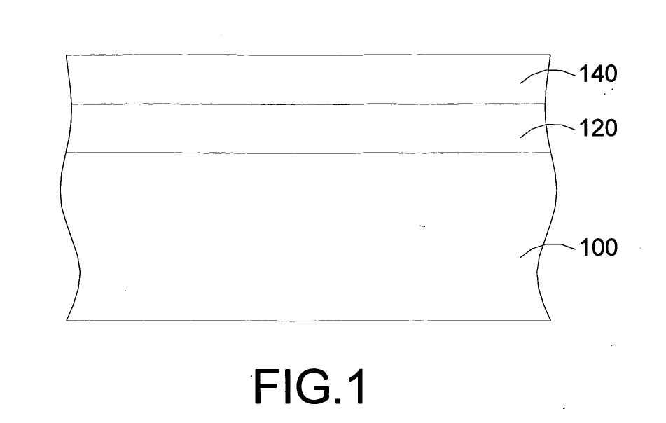

The present invention discloses an exposure method of forming a three-dimensional lithographic pattern, which implements multiple layers of photoresist and multiple reticles with multiple exposure steps in one lithographic process to form a desired three-dimensional pattern. As a result, the frequency of a substrate uploading to or offloading from a lithography equipment is reduced, so that the process flow is simplified, the production cost is reduced, and the throughput is increased. FIGS. 1 to 3C illustrate preferred embodiments of the present invention.

Referring to FIG. 1, in one embodiment, the present invention provides an exposure method of forming a three-dimensional lithographic pattern. The three-dimensional lithographic pattern can be, for example, a dual damascene pattern, or a bottle-like pattern. The method includes a step of providing a substrate 100, which can be a semiconductor substrate or an incomplete semiconductor device. The semiconductor substrate can be, for example, but not limit to a silicon (Si) substrate, a germanium (Ge) substrate, a semiconductor on insulator (SOI), a silicon germanium on insulator (SGeOI). The incomplete semiconductor device can be any substrate during the process flow of manufacturing a semiconductor device, for example, a substrate to be formed with a interconnect or any substrate to be formed with a three-dimensional pattern therein as appropriate.

A first photoresist layer 120 is then formed on the substrate 100. The first photoresist layer 120 corresponds to a first exposure removal dose. It is noted that the exposure removal dose represents an exposure energy required to make the photoresist, after the exposure step, become substantially removable in a development process. In other words, when the photoresist is exposed with an exposure energy smaller than the exposure removal dose, the exposed photoresist region remains irremovable in the development step, and the desired pattern cannot be formed. When the photoresist layer is exposed with an exposure energy substantially equal to or higher than the exposure removal dose, the exposed photoresist becomes removable in the development step, and a desired pattern can be formed. A second photoresist layer 140 is then formed on the first photoresist layer 120. The second photoresist layer 140 corresponds to a second exposure removal dose, which is different from the first exposure removal dose. In an exemplary embodiment, the first exposure removal dose is higher than the second exposure removal dose. In other words, the first photoresist layer 120 requires an energy higher than that of the second photoresist layer 140 so as to be removed in a development process after the exposure step. It is noted that the present invention is applicable to a positive photoresist or a negative photoresist. In this embodiment, positive photoresists are illustrated.

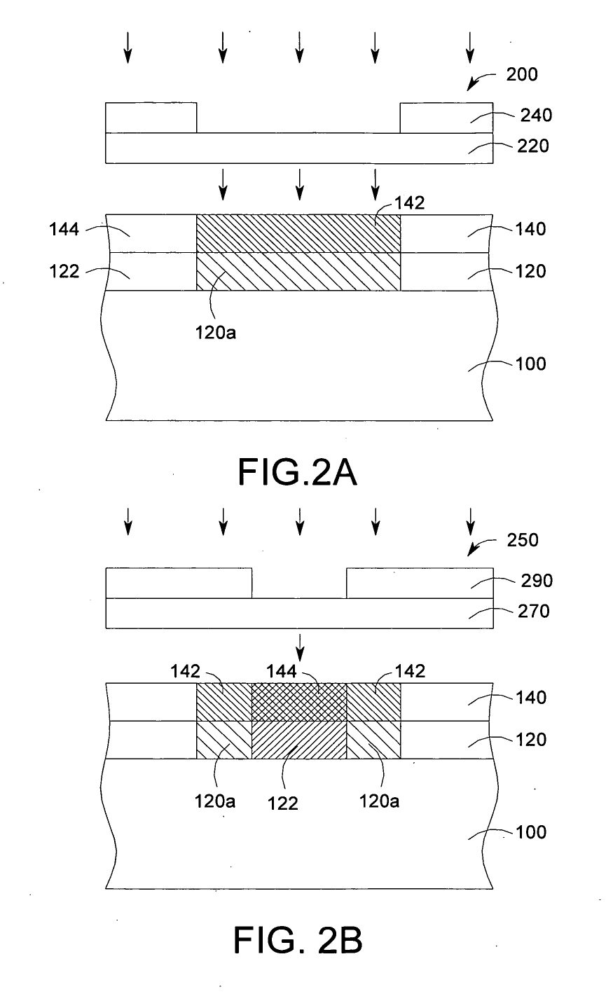

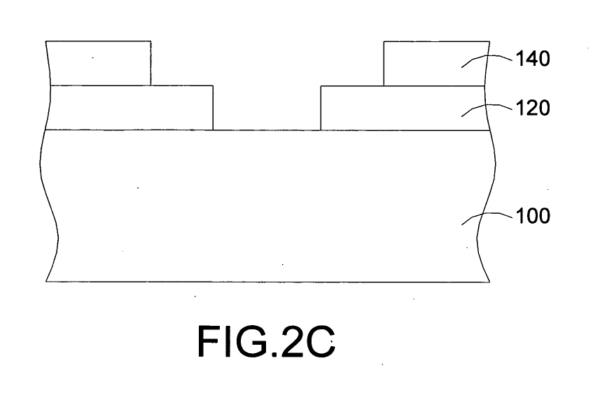

Referring to FIG. 2A, through a first reticle 200, the first photoresist layer 120 and the second photoresist layer 140 are exposed with a first exposure energy, which is in a range between the first exposure removal dose and the second exposure removal dose, so as to form a first removable region 142. As shown in FIG. 2A, the first reticle 200 includes a transparent substrate 220 and an opaque layer 240. The light transmittance is substantially 100% for the transparent substrate 220 and 0 for the opaque layer 240. The transparent substrate 220 includes, for example, a glass substrate, a quartz substrate, or any transparent substrate for a conventional reticle as appropriate. The opaque layer 240 can be a metal layer, such as a chromium layer. As shown in FIG. 2A, the opaque layer 240 is patterned and arranged on the transparent substrate 220 so as to form a partial portion of a desired three-dimensional pattern, such as trench of a dual damascene pattern. It is noted that though the present invention is illustrated in cross-sectional views, the patterns of the reticles can vary with the design need of different devices and are not limited to the embodiments.

The present invention implements a first exposure step with the first exposure energy, which is in a range between the first exposure removal dose and the second exposure removal dose, so that the first photoresist layer 120 and the second photoresist layer 140 are exposed through the first reticle 200. Accordingly, the removable region is formed substantially only in one of these two photoresist layers while the exposed region in the other photoresist layer lacks sufficient energy to transform into a removable region and cannot be removed in a subsequent development step. For example, in this exemplary embodiment, the first exposure energy is substantially equal to or larger than the second exposure removal dose and less than the first exposure removal dose. Therefore, after the first photoresist layer 120 and the second photoresist layer 140 are exposed with the first exposure energy, the removable region 142 is formed substantially only in the second photoresist layer 140. Though the region of the first photoresist layer 120 corresponding to the removable region 142 (i.e. the region 120a) is exposed with the first exposure energy, due to the lack of sufficient energy (i.e. less than the first exposure removal dose), the exposed region 120a cannot be removed in a subsequent development step.

It is noted that in one embodiment, when the difference between the first exposure removal dose and the second exposure removal dose is small, the first exposure energy is preferably selected to be substantially equal to the second exposure removal dose. As such, it can prevent an undesired pattern from forming in the first photoresist layer 120 due to the influence of noise. Alternatively, when the difference between the first exposure removal dose and the second removal dose is significant, the first exposure energy is preferably selected to be slightly higher than the second exposure removal dose so as to ensure that the desired removable region 142 in the second photoresist layer 140 is fully exposed, and therefore, to enhance the resolution.

Then, through a second reticle 250, the first photoresist layer 120 and the second photoresist layer 140 are exposed with a second exposure energy, which is substantially equal to or higher than the higher one of the first exposure removal dose and the second exposure removal dose, so as to form a second removable region 122 different from the first removable region 142, as shown in FIG. 2B. For example, in this embodiment, the second reticle 250 includes a transparent substrate 270 and an opaque layer 290. The transparent substrate 270 and the opaque layer 290 can be formed by materials similar to those of the first reticle 200. The opaque layer 290 is patterned and arranged in the transparent substrate 270 so as to form another portion of the desired three-dimensional pattern, such as via of a dual damascene pattern. Though two reticles are employed to form the desired three-dimensional pattern, it is noted that the possible number of the reticles and the number of the photoresist layers used to form the desired three-dimensional pattern are not limited to the embodiments. In this embodiment, after the step of exposing with the first exposure energy, the first photoresist layer 120 and the second 140 are then exposed with the second exposure energy, which is substantially equal to or higher than the first exposure removal dose. Accordingly, the second removable region 122 is formed in the first photoresist layer 120, as shown in FIG. 2B. In other words, a portion of the region 120a of the first photoresist layer 120 is transformed into the second removable region 122 due to the sufficient energy provided by the second exposure step. Moreover, the region 144 in the second photoresist layer 140 is a double exposed region, which overlaps the second removable region 122. That is, the second removable region 122 substantially partially overlaps the first removable region 142. The method further includes a step of developing the first photoresist layer 120 and the second photoresist layer 140 so as to remove the first removable region 142 and the second removable region 122 so as to form the desired three-dimensional pattern is formed, as shown in FIG. 2C.

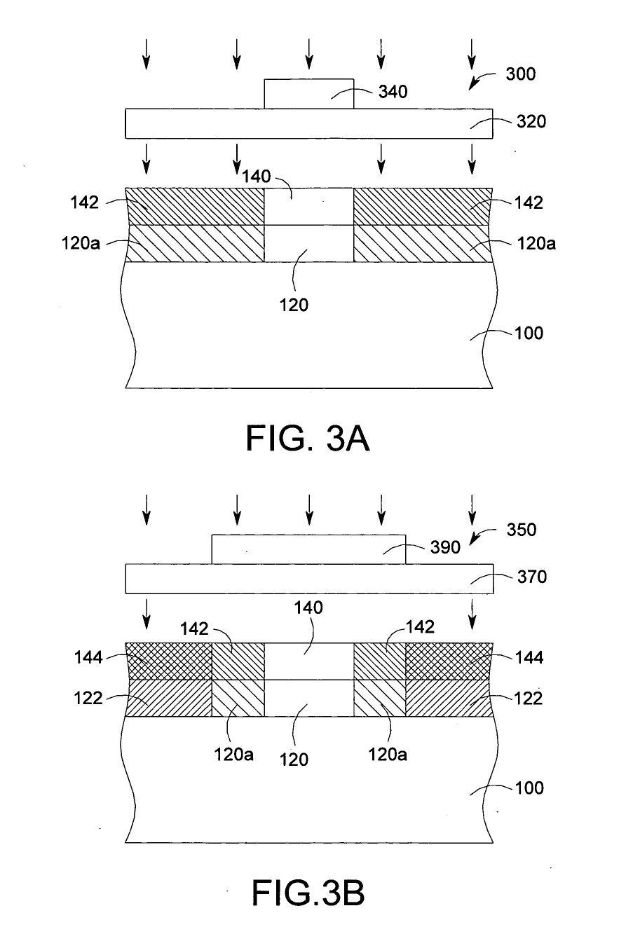

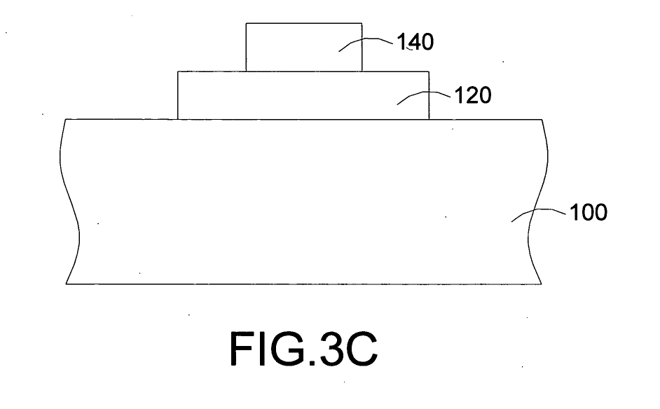

Referring to FIG. 3A, in another embodiment of the present invention, different reticles cooperated with dual layers of photoresist are implemented to form a lithographic pattern as illustrated in FIG. 3C. As shown in FIG. 3A, an opaque layer 340 designed based on the device need is patterned and arranged on a transparent substrate 320 so as to form a first reticle 300. In this embodiment, through the first reticle 300, the first photoresist layer 120 and the second photoresist layer 140 are exposed with a first exposure energy, which is in a range between the first exposure removal dose and the second exposure removal dose, so as to form a first removable region 142 substantially only in the second photoresist layer 140. Though the region of the first photoresist layer 120 corresponding to the removable region 142 (i.e. the region 120a) is exposed with the first exposure energy, due to the lack of sufficient energy (i.e. less than the first exposure removal dose), the exposed region 120a cannot be removed in a subsequent development step.

Referring to FIG. 3B, in this embodiment, a second reticle 350 includes a transparent substrate 370 and an opaque layer 390. The transparent substrate 370 and the opaque layer 390 can be formed by materials similar to those of the first reticle 300. The opaque layer 390 is patterned and arranged in the transparent substrate 370 so as to form another portion of the desired three-dimensional pattern. Through the second reticle 350, the first photoresist layer 120 and the second 140 are then exposed with the second exposure energy, which is substantially equal to or higher than the first exposure removal dose. Accordingly, the second removable region 122 is formed in the first photoresist layer 120, as shown in FIG. 3B. In other words, a portion of the region 120a of the first photoresist layer 120 is transformed into the second removable region 122 due to the sufficient energy provided by the second exposure step. Moreover, the region 144 in the second photoresist layer 140 is a double exposed region, which overlaps the second removable region 122. That is, the second removable region 122 substantially partially overlaps the first removable region 142. The method further includes a step of developing the first photoresist layer 120 and the second photoresist layer 140 so as to remove the first removable region 142 and the second removable region 122 so as to form the desired three-dimensional pattern is formed, as shown in FIG. 3C.

The present invention implements multiple layers of photoresist (such as layers 120, 140) and multiple reticles (such as 200, 250 or 300, 350) with multiple exposure steps (such as the first and the second exposure energies) in one lithographic process to form a desired removable region in each photoresist layer (such as regions 142, 122). A desired three-dimensional pattern is then created in a single development step. In comparison with conventional technologies, the present invention reduces the frequency of a substrate uploading to or offloading from a lithography equipment, resulting in the simplification of the process flow, the reduction of the production cost, and the increase in the throughput.

It is noted that the selection of the first and the second photoresist layers preferably respectively corresponds to exposure removal doses with significant difference so as to minimize the influence of noise and to facilitate the manipulation of the exposure energy.

Although specific embodiments have been illustrated and described, it will be obvious to those skilled in the art that various modifications may be made without departing from what is intended to be limited solely by the appended claims.

What is claimed is:

1. An exposure method of forming a three-dimensional lithographic pattern, comprising:
providing a substrate;
forming a first photoresist layer on said substrate, said first photoresist layer corresponding to a first exposure removal dose;
forming a second photoresist layer on said first photoresist layer, said second photoresist layer corresponding to a second exposure removal dose different from said first exposure removal dose;
through a first reticle, exposing said first and said second photoresist layers with a first exposure energy so as to form a first removable region, said first exposure energy being in a range between said first exposure removal dose and said second exposure removal dose; and
through a second reticle, exposing said first and said second photoresist layers with a second exposure energy so as to form a second removable region, wherein said second exposure energy is substantially equal to or higher than the higher one of said first exposure removal dose and said second exposure removal dose.

2. The exposure method of claim 1, wherein said substrate comprises a semiconductor substrate or an incomplete semiconductor device.

3. The exposure method of claim 1, wherein said first exposure removal dose is higher than said second exposure removal dose.

4. The exposure method of claim 1, wherein said step of exposing with said first exposure energy forms said first removable region substantially only in said second photoresist layer.

5. The exposure method of claim 4, wherein said step of exposing with said second exposure energy forms said second removable region substantially partially overlapping said first removable region.

6. The exposure method of claim 1, further comprising a step of developing said first and said second photoresist layers so as to remove said first and said second removable regions.

7. The exposure method of claim 6, wherein after the developing step, a three-dimensional pattern is formed, and said three-dimensional pattern comprises a dual damascene pattern or a bottle-like pattern.

8. An exposure method of forming a three-dimensional lithographic pattern, comprising:
providing a substrate;
forming a first photoresist layer on said substrate, said first photoresist layer corresponding to a first exposure removal dose;
forming a second photoresist layer on said first photoresist layer, said second photoresist layer corresponding to a second exposure removal dose smaller than said first exposure removal dose;
through a first reticle, exposing said first and said second photoresist layers with a first exposure energy so as to form a first removable region substantially only in said second photoresist layer, said first exposure energy being larger in a range between said first exposure removal dose and said second exposure removal dose; and
through a second reticle, exposing said first and said second photoresist layers with a second exposure energy substantially equal to or higher than said first exposure removal dose so as to form a second removable region in said first photoresist layer, said second removable region substantially partially overlapping said first removable region.

9. The exposure method of claim 8, wherein said substrate comprise a semiconductor substrate or an incomplete semiconductor device.

10. The exposure method of claim 8, further comprising a step of developing said first and said second photoresist layers so as to remove said first and said second removable regions.

11. The exposure method of claim 10, wherein after the developing step, a three-dimensional pattern is formed, and said three-dimensional pattern comprises a dual damascene pattern or a bottle-like pattern.
